(19) United States
(12) Patent Application Publication
(10) Pub. No.: US 2024/0145408 A1
(43) Pub. Date: May 2, 2024

(54) CHIP WITH CRACK GUIDING STRUCTURE COMBINED WITH CRACK STOP STRUCTURE

(71) Applicant: Infineon Technologies AG, Neubiberg (DE)

(72) Inventors: Maria HEIDENBLUT, Schwarzenfeld (DE); Michael GOROLL, Poing (DE); Stefan KAISER, Aschheim (DE); Sergey ANANIEV, Unterhaching (DE); Sabine BOGUTH, Schleching (DE); Gunther MACKH, Neumarkt (DE); Andreas BAUER, Regensburg (DE); Georg Michael REUTHER, Augsburg (DE)

(73) Assignee: Infineon Technologies AG, Neubiberg (DE)

(21) Appl. No.: 18/378,858

(22) Filed: Oct. 11, 2023

(30) Foreign Application Priority Data
Oct. 26, 2022 (DE) 10 2022 128 335.6

(51) Int. Cl. H01L 23/00; H01L 21/78; H01L 23/31; H01L 23/58

(52) U.S. Cl. CPC H01L 23/562; H01L 21/78; H01L 23/3107; H01L 23/585

(57) ABSTRACT

An electronic chip is disclosed. In one example, the electronic chip comprises a substrate comprising a central portion and an edge portion around at least part of the central portion. An active region is arranged in the central portion. A crack guiding structure combined with a crack stop structure is provided, both being arranged in the edge portion.

### CROSS-REFERENCE TO RELATED APPLICATION

This Utility patent application claims priority to German Patent Application No. 10 2022 128 335.6 filed Oct. 26, 2022, which is incorporated herein by reference.

### BACKGROUND

### Technical Field

Various embodiments relate generally to an electronic chip, a package, and a manufacturing method.

### Description of the Related Art

A conventional package may comprise a semiconductor component mounted on a carrier such as a leadframe structure, may be electrically connected by a bond wire extending from the semiconductor component to the carrier, and may be molded using a mold compound as an encapsulant.

During the process of separating an electronic chip from a wafer compound, for instance by dicing, cracks may occur which may damage the electronic chip.

### SUMMARY

There may be a need for an electronic chip having a high reliability.

According to an exemplary embodiment, an electronic chip is provided which comprises a substrate comprising a central portion and an edge portion around at least part of the central portion, an active region arranged in the central portion, and a crack guiding structure combined with a crack stop structure, both being arranged in the edge portion of the substrate of the chip.

According to another exemplary embodiment, a package is provided which comprises a carrier, an electronic chip having the above-mentioned features and being mounted on the carrier, and an encapsulant encapsulating at least part of the electronic chip and the carrier.

According to still another exemplary embodiment, a manufacturing method is provided which comprises providing a wafer comprising a plurality of integrally connected electronic chips having the above-mentioned features, and separating the electronic chips from the wafer along separation lines extending between adjacent edge portions of the electronic chips so that at least part of cracks created during the separating are guided along the crack guiding structures and/or are stopped by the crack stop structures.

According to an exemplary embodiment, an electronic chip is equipped at a peripheral or edge portion, surrounding a central active chip region partially or entirely, with a crack guiding structure combined with a crack stop structure. When the electronic chip is separated from a wafer compound by dicing at the end of a manufacturing process, cracks which may be generated during the dicing process may be spatially guided in a controlled way by a crack guiding structure towards regions being sufficiently remote from the sensitive active region where cracks may have damaging and destructive consequences. Thus, the specifically crack sensitive active region may be reliably protected against cracks by guiding or directing cracks away from the active region. Moreover, the aforementioned crack guiding structure may be combined, functionally and/or structurally, with a crack stop structure inhibiting propagation or spreading of a guided crack by exerting a stopping force to and/or by removing energy from a crack created by chip separation. In particular the combination of crack guiding and crack stopping by a combined structural and/or functional configuration of the edge portion of the electronic chip provides a highly reliable protection of sensitive chip portions against crack-caused damages. As a result, an electronic chip may be manufactured with high reliability.

### BRIEF DESCRIPTION OF THE DRAWINGS

The accompanying drawings, which are included to provide a further understanding of exemplary embodiments and constitute a part of the specification, illustrate exemplary embodiments.

In the Drawings:

FIG. 1 illustrates a cross-sectional view of an electronic chip according to an exemplary embodiment.

FIG. 2 illustrates a flowchart of a manufacturing method according to an exemplary embodiment.

FIG. 3 illustrates a cross-sectional view of an electronic chip according to an exemplary embodiment.

FIG. 4 illustrates an image of an electronic chip according to another exemplary embodiment.

FIG. 5 illustrates a cross-sectional view of electronic chips of a common wafer according to an exemplary embodiment.

FIG. 6 illustrates a cross-sectional view of a package according to an exemplary embodiment.

FIG. 7 illustrates a cross-sectional view of an electronic chip according to yet another exemplary embodiment in which different kinds of cracks are illustrated.

FIG. 8 illustrates a cross-sectional view of an electronic chip according to yet another exemplary embodiment.

FIG. 9 illustrates a cross-sectional view of an electronic chip according to still another exemplary embodiment.

### DETAILED DESCRIPTION

There may be a need for an electronic chip having a high reliability.

According to an exemplary embodiment, an electronic chip is provided which comprises a substrate comprising a central portion and an edge portion around at least part of the central portion, an active region arranged in the central portion, and a crack guiding structure combined with a crack stop structure, both being arranged in the edge portion of the substrate of the chip.

According to another exemplary embodiment, a package is provided which comprises a carrier, an electronic chip having the above-mentioned features and being mounted on the carrier, and an encapsulant encapsulating at least part of the electronic chip and the carrier.

According to still another exemplary embodiment, a manufacturing method is provided which comprises providing a wafer comprising a plurality of integrally connected electronic chips having the above-mentioned features, and separating the electronic chips from the wafer along separation lines extending between adjacent edge portions of the electronic chips so that at least part of cracks created during the separating are guided along the crack guiding structures and/or are stopped by the crack stop structures. According to an exemplary embodiment, an electronic chip is equipped at a peripheral or edge portion, surrounding a central active chip region partially or entirely, with a crack guiding structure combined with a crack stop structure. When the electronic chip is separated from a wafer compound by dicing at the end of a manufacturing process, cracks which may be generated during the dicing process may be spatially guided in a controlled way by a crack guiding structure towards regions being sufficiently remote from the sensitive active region where cracks may have damaging and destructive consequences. Thus, the specifically crack sensitive active region may be reliably protected against cracks by guiding or directing cracks away from the active region. Moreover, the aforementioned crack guiding structure may be combined, functionally and/or structurally, with a crack stop structure inhibiting propagation or spreading of a guided crack by exerting a stopping force to and/or by removing energy from a crack created by chip separation. In particular the combination of crack guiding and crack stopping by a combined structural and/or functional configuration of the edge portion of the electronic chip provides a highly reliable protection of sensitive chip portions against crack-caused damages. As a result, an electronic chip may be manufactured with high reliability.

In the following, further exemplary embodiments of the electronic chip, the package, and the method will be explained.

In the context of the present application, the term “electronic chip” may in particular encompass any chip providing an electronic functionality. For instance, the electronic chip may be a semiconductor chip (in particular a power semiconductor chip), an active electronic device (such as a transistor), a passive electronic device (such as a capacitance or an inductance or an ohmic resistance), a sensor (such as a microphone, a light sensor or a gas sensor), an actuator (for instance a loudspeaker), and a microelectromechanical system (MEMS). However, in other embodiments, the electronic chip may also be of different type, such as a mechatronic member, in particular a switch, etc. In particular, the electronic chip may be a semiconductor chip having at least one integrated circuit element (such as a diode or a transistor) in a surface portion thereof. The electronic chip may be a bare die or may be already packaged or encapsulated. Electronic chips implemented according to exemplary embodiments may be formed for example in silicon technology, gallium nitride technology, silicon carbide technology, etc.

In the context of the present application, the term “substrate” may particularly denote a carrier body of the electronic chip. In particular, the substrate may comprise a semiconductor material such as silicon.

In the context of the present application, the term “active region” may particularly denote a region in a central portion of a substrate in which at least one integrated circuit element may be formed, in particular at least one monolithically integrated circuit element. For instance, such an integrated circuit element may be a transistor (in particular a field effect transistor), a diode, etc.

In the context of the present application, the term “crack” may particularly denote a break, fissure or fracture in a substrate which may be created for example when separating a substrate for singulating an electronic chip. In particular, such a crack may move or propagate along the substrate and may thereby extend up to or into sensitive regions (in particular an active chip area, where the crack may cause damage. According to exemplary embodiments, measures may be taken for suppressing uncontrolled crack propagation.

In the context of the present application, the term “crack guiding structure” may particularly denote a physical (preferably metallically delimited) arrangement in a substrate which strongly promotes or even enforces propagation of a crack along a predefined spatial target trajectory while simultaneously strongly suppressing or even disabling propagation of a crack apart from said predefined spatial target trajectory. Hence, a crack guiding structure may define or control a motion path of a propagating crack without necessarily stopping or decelerating it. A crack guiding structure may relate to a dielectric substrate portion.

In the context of the present application, the term “crack stop structure” may particularly denote a physical (preferably metallic) structure in a substrate which is configured for inhibiting or even disabling continued propagation of a crack. In particular, a crack stop structure may comprise or consist of metallic structures in a dielectric or semiconductive surrounding. A crack stop structure may be arranged and configured so that a propagating crack is bounced off by the crack stop structure into a less harmful region and/or is absorbed by the crack stop structure and thereby loses at least part of its propagation energy and therefore decelerates or even stops. Depending on the mechanical robustness of the crack stop structure, the crack stop structure may withstand an approaching crack without being destroyed itself. It is however also possible that at least part of the crack stop structure, which is then embodied as sacrificial structure, is configured to be destroyed or sacrificed when stopping or at least decelerating a crack.

In the context of the present application, the term “crack guiding structure combined with crack stop structure” may particularly denote a spatial and material configuration in a portion of the substrate which may simultaneously and/or synergetically guide a crack along a predefined trajectory and/or may apply a decelerating or even stopping force to the crack. This may ensure simultaneously that the crack is directed into a desired spatial region of the substrate while losing at least part of its energy so that crack propagation can be inhibited or even completely stopped. The crack guiding structure may be functionality coupled with the crack stop structure. It is also possible that the crack guiding structure is integrally formed with the crack stop structure, for instance is formed inside the crack stop structure.

In the context of the present application, the term “package” may particularly denote an electronic device which may comprise one or more electronic chips (such as semiconductor components) mounted on a carrier (such as a leadframe structure, etc.). Said constituents of the package may be encapsulated at least partially by an encapsulant. Optionally, one or more electrically conductive connection elements (such as metallic pillars, bumps, needles, bond wires and/or clips) may be implemented in a package, for instance for electrically coupling and/or mechanically supporting the electronic chip.

In the context of the present application, the term “encapsulant” may particularly denote a substantially electrically insulating material configured for surrounding at least part of an electronic chip and at least part of one or more electrically conductive structures to provide mechanical protection, electrical insulation, and optionally a contribution to heat removal during operation. In particular, said encapsulant may be a mold compound. A mold compound may comprise a matrix of flowable and hardenable material and filler particles embedded therein. For instance, filler particles may be used to adjust the properties of the mold component. It is also possible that a semiconductor package encapsulant is a potting or casting compound.

In the context of the present application, the term “carrier” may particularly denote a support structure (which may be at least partially electrically conductive) which serves as a mechanical support for the electronic chip(s) to be mounted thereon, and which may also contribute to the electric interconnection between the electronic chip(s) and the periphery of the package. In other words, the carrier may fulfil a mechanical support function and an electric connection function. A carrier may comprise or consist of a single part, multiple parts joined via encapsulation or other package components, or a subassembly of carriers. For example, the carrier is a metal plate or forms part of a leadframe. However, it is also possible that the carrier comprises a stack composed of a central electrically insulating and thermally conductive layer (such as a ceramic layer) covered on both opposing main surfaces by a respective electrically conductive layer (such as a copper layer or an aluminium layer, wherein the respective electrically conductive layer may be a continuous or a patterned layer). In particular, the carrier may be a Direct Copper Bonding (DCB) substrate or a Direct Aluminium Bonding (DAB) substrate. However, the carrier may also be configured as Active Metal Brazing (AMB) substrate, or as patterned metal plate (for example a leadframe).

In the context of the present application, the term “wafer” may particularly denote a semiconductor body (in particular plate) which has been processed to form a plurality of integrated circuit elements in active regions of the wafer and which may be singularized into a plurality of separate electronic chips. For example, a wafer may have a disk shape and may comprise a matrix-like arrangement of electronic chips in rows and columns. It is possible that a wafer has a circular geometry or a polygonal geometry (such as a rectangular geometry or a triangular geometry).

In an embodiment, the crack guiding structure defines a spatially confined crack propagation path at least partially inside of the crack stop structure. In particular, the crack guiding structure may define a channel along which a created crack will propagate in a controlled way. Generally, a crack will propagate along a path of least mechanical resistance. Thus, the crack guiding structure may be arranged close to a likely crack creation position so that a generated crack will automatically enter the defined crack guiding channel. Advantageously, both opposing sides of a crack guiding channel may be defined or delimited by the crack stop structure so that a crack tending to move out of the crack guiding channel will be stopped or reflected into the crack guiding channel.

In an embodiment, the crack guiding structure is configured for redirecting a propagation direction of a crack when passing the crack guiding structure combined with the crack stop structure. Preferably, the crack guiding structure is configured for redirecting a crack propagating towards the active region into an upwardly propagating crack, wherein in particular the crack guiding structure is configured for further redirecting the upwardly propagating crack into a crack propagating laterally away from the active region. For example, a generated crack may propagate along a substantially straight direction in the absence of an external influence. When configuring the crack guiding structure appropriately, in particular when confining it inside of the crack stop structure, a curved or angled propagation path may be defined as a region of least mechanical resistance between crack stop structure elements. Redirecting a crack propagation direction may allow to guide the crack away from potentially harmful regions of the substrate, in particular away from the active region. This may reliably prevent the electronic chip from crack-caused damage.

In an embodiment, the crack stop structure is configured for stopping a crack, as a barrier for a crack and/or for absorbing energy of a crack. A moving crack in a substrate may carry kinetic energy. For stopping a propagating crack, said kinetic energy has to be dissipated. The crack stop structure can be configured as a robust mechanical structure causing the crack to dissipate its energy partially or entirely to thereby lose velocity and finally discontinue propagating. It is also possible that the crack stop structure forms a barrier wall rendering it impossible for a propagating crack to pass said barrier wall, thereby preventing the crack from entering into undesired regions.

In an embodiment, the substrate comprises a semiconductor body with a back end of the line (BEOL) structure thereon, wherein the crack guiding structure combined with the crack stop structure form part of the back end of the line structure. For instance, the semiconductor body may be a silicon body in which one or more integrated circuit elements may be (in particular monolithically) integrated for forming the above-mentioned active region. The back end of the line may denote a second portion of integrated circuit fabrication where individual integrated circuit elements (such as transistors, capacitors, resistors) get interconnected with wiring on the semiconductor body (or, before dicing, the wafer). More specifically, the back end of the line may comprise at least one metallization layer in a dielectric surrounding. The back end of the line may begin with a first layer of metal deposited on the semiconductor body below. The back end of the line may include contacts, insulating layers, metal levels, and bonding sites for chip-to-package connections.

In an embodiment, the crack guiding structure defines a dielectric path delimited by metallic structures of the crack stop structure, wherein in particular the dielectric path comprises a bottom-sided upward path section merging into a top-sided lateral path section. The dielectric path may be defined by dielectric material of a back end of the line structure on a semiconductor body. Said dielectric material defining a crack guiding channel may be at least partially laterally surrounded by metallic material delimiting the dielectric crack propagation path and forming at least part of the crack stop structure.

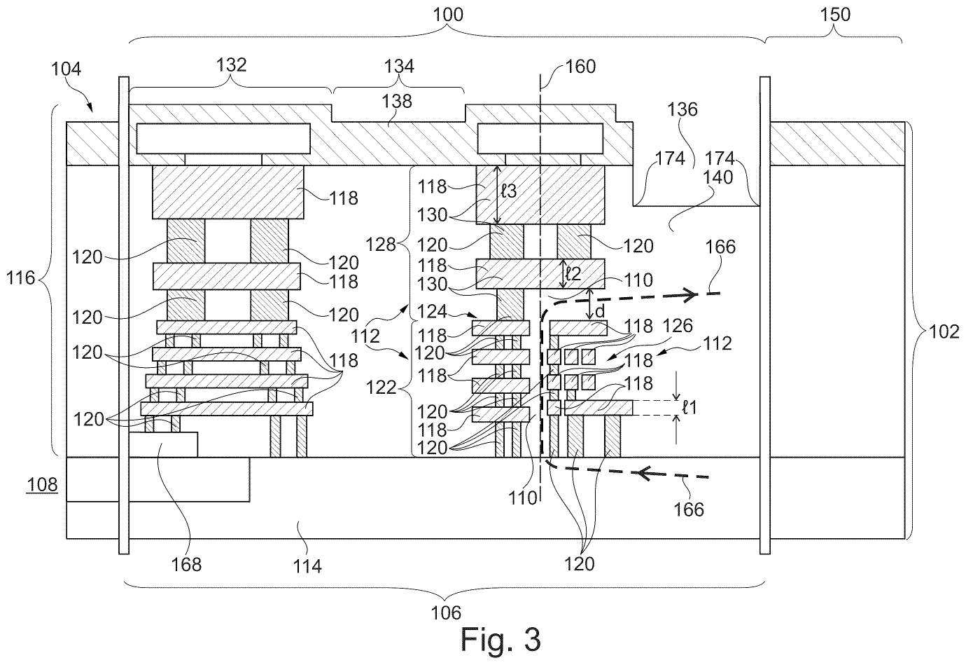

In an embodiment, the crack stop structure comprises horizontal metallic structures and vertical metallic structures. A number of horizontal metallic structures and vertical metallic structures of the crack stop structure may be freely selected (for instance, FIG. 3 shows six metal layers in a BEOL dielectric). For example, the horizontal metallic structures may be pads, wiring structures and/or layer structures, for instance each forming part of a planar patterned metal layer. The vertical metallic structures may be vias which may interconnect horizontal metallic structures at different vertical levels with each other. Such a metallic configuration may provide a crack stop function and may be manufacturable with reasonable effort.

In an embodiment, a bottom-sided portion of the crack stop structure comprises a crack barrier section facing the active region and comprises a sacrificial section facing away from the active region. At least part of the crack guiding structure may for example extend between the crack barrier section and the sacrificial section. The crack barrier section may be configured to act as a mechanical or physical barrier for a propagating crack. Descriptively speaking, the crack barrier section may function as an impermeable wall separating a crack propagating along the crack guide structure with respect to the active region. On the opposing side of the crack guide structure in relation to the crack barrier section, a sacrificial section may be arranged which is configured to be at least partially destroyed by a propagating crack when the crack deposits at least part of its energy in the sacrificial section. Since the sacrificial section is arranged facing away from the active region with the crack barrier section in between, there is no risk that the active region is harmed when the sacrificial section is destroyed during stopping a crack.

In an embodiment, the crack barrier section is configured as a barrier for inhibiting propagation of a crack through the crack barrier section towards the active region. For this purpose, the crack barrier section may comprise a continuously interconnected vertical arrangement of horizontal metallic structures and vertical metallic structures. More specifically, the crack barrier section may be configured as an alternating sequence of horizontal and vertical metallic structures. Such a crack barrier section can be manufactured in a simple way and provides a high robustness.

In an embodiment, the sacrificial section is configured for being at least partially destroyed by a crack propagating to the crack stop structure. This intentional relatively low robustness of the sacrificial section against propagating cracks may be achieved by forming at least some of horizontal metallic structures in the sacrificial section without interconnecting vertical metallic structures in between, in particular without interconnecting vias.

In an embodiment, the sacrificial section comprises horizontal metallic structures and vertical metallic structures, wherein a part of the horizontal metallic structures is interconnected with the vertical metallic structures, and wherein another part of the horizontal metallic structures is separated from the vertical metallic structures and is thereby floating in a dielectric environment. By isolating part of the horizontal metallic structure from another metallic structures, vertically unconnected and surrounded by dielectric medium, the robustness of the sacrificial section may be intentionally reduced. By taking this measure, it may be ensured that a crack propagating through the sacrificial section is predominantly not reflected but absorbed by the sacrificial section which can thereby be partially destroyed. Hence, the functional difference between the sacrificial section (i.e. predominantly crack absorption) on the one hand and of the crack barrier section (i.e. predominantly functioning as impenetrable wall) on the other hand may be enhanced by the varying configuration of the horizontal metallic structures and the vertical metallic structures in both sections.

Advantageously, vertical levels of horizontal metal structures and of vertical metallic structures in between may be the same in the crack barrier section as in the sacrificial section. Consequently, both the crack barrier section and the sacrificial section may be manufactured simultaneously and hence with low effort.

In an embodiment, a number of vertical metallic structures per volume is larger in the crack barrier section than in the sacrificial section. Intentionally keeping at least part of the horizontal metallic structures unconnected by vertical metallic structures in the sacrificial section and interconnecting all horizontal metallic structures by vertical metallic structures in the crack barrier section may introduce an intended lateral symmetry in the crack stop structure leading to the different mentioned functions of the crack barrier section and the sacrificial section.

In an embodiment, a top-sided portion of the crack stop structure comprises a metallic bulk structure extending vertically from and being connected with the crack barrier section. In this context, a metallic bulk structure may denote one or more metallic clusters of larger size in the top-sided portion of the crack stop structure as compared to its bottom-sided portion. A via distribution (more generally a distribution of vertical metallic structures) of the metallic bulk structure may be either symmetric or asymmetric. This symmetry or asymmetry of the metallic bulk structure may be with respect to a symmetry axis (see reference sign 152 in FIG. 7) which extends along a vertical direction. To put it shortly, the metallic bulk structure may function as a strong inhibitor for continued crack propagation into the metallic bulk structure. For example, an asymmetrically arranged metallic bulk structure may intentionally tilt or collapse upon exertion of mechanical stress by a propagating crack, thereby efficiently contributing to crack stopping.

In an embodiment, the metallic bulk structure is separated by a vertical spacing from the sacrificial section and extends laterally over at least part of the sacrificial section. In other words, the metallic bulk structure may be spatially separated from the sacrificial section, in particular by a dielectric portion of the crack guiding structure. At the same time, the metallic bulk structure may extend horizontally so as to cover also at least part of the sacrificial section below, for instance as a cantilever. Thereby, the metallic bulk structure may contribute also to the definition of the crack guiding structure. Furthermore, the metallic bulk structure may be directly connected with the crack barrier structure and may form a vertical continuation of the latter.

More specifically, the sub-tower constituted by the sacrificial section does not extend with its uppermost metal layer up to the height of the adjacent tower constituted by the crack barrier section. The vertical continuation of the adjacent crack barrier section in form of the metallic bulk structure may at least partially cover the sub-tower constituting the sacrificial section with at least one metal layer, without being connected in the cover region with vias to the sub-tower of the sacrificial section.

In an embodiment, a top-sided portion of the crack stop structure comprises an asymmetric metallic bulk structure having a higher amount of metal per volume on a side facing the active region than on an opposing side facing away from the active region. An asymmetric metal distribution of the crack stop structure with more metal of crack barrier section and metallic bulk structure facing the active region as compared to less metal of the sacrificial structure facing away from the active region may strongly protect the active region against cracks while directing the cracks away from the active region along the crack guiding structure and towards the sacrificial structure for dissipation. Hence, the asymmetric metallic bulk structure of the top-sided portion of the crack stop structure may have a higher amount of metal per volume than each of the crack barrier section and the sacrificial section of the bottom-sided portion of the crack stop structure. Thus, the crack stop structure may be asymmetric with respect to a vertical central axis through the crack stop structure.

In an embodiment, the crack stop structure comprises a plurality of vertically stacked and mutually spaced horizontal metal structures having a thickness which increases from bottom to top of the crack stop structure. In other words, an upper horizontal metal structure above another lower horizontal metal structure of the crack stop structure may have a higher thickness than or the same thickness as the lower horizontal metal structure. Thus, the metal thickness may increase with increasing vertical level of the layers. However, one or some adjacent of the horizontal metal layers can also have the same thickness. Such a stepped continuous increase (optionally with one or more plateaus in between) of the thickness of the horizontal metal layers of the crack stop structure may lead to an increasing metal density from bottom to top of the crack stop structure. Furthermore, all horizontal metal layers can have the same thickness in another embodiment.

In an embodiment, the electronic chip comprises a seal ring arranged laterally between the active region on the one hand and the crack guiding structure combined with the crack stop structure on the other hand. Such a seal ring may be configured for protecting the active region against moisture and charged particles. A seal ring may be formed based on alternating horizontal metallic layers and vertical metallic layers configured for providing the mentioned function of circumferentially sealing the active region.

In an embodiment, the electronic chip may comprise a zone for optical inspection of integrity of the electronic chip, said zone being arranged laterally between the seal ring on the one hand and the crack guiding structure combined with the crack stop structure on the other hand. In particular, such an intermediate zone between seal ring and combined crack stop and guiding structure may be used for automatic optical inspection by an optical camera or for manual inspection by a human operator. An optical microscope may be used for the purpose of optical inspection. If a crack is identified in said inspection zone, the electronic chip may be classified as waste or scrap. In the absence of a crack in said inspection zone, the electronic chip may have passed the optical quality check. Hence, the electronic chip may be subject to a simple optical test due to its construction.

In an embodiment, the electronic chip is configured as bare die, i.e. as a semiconductor chip without encapsulation. Alternatively, the electronic chip may be encapsulated, for instance by a mold compound.

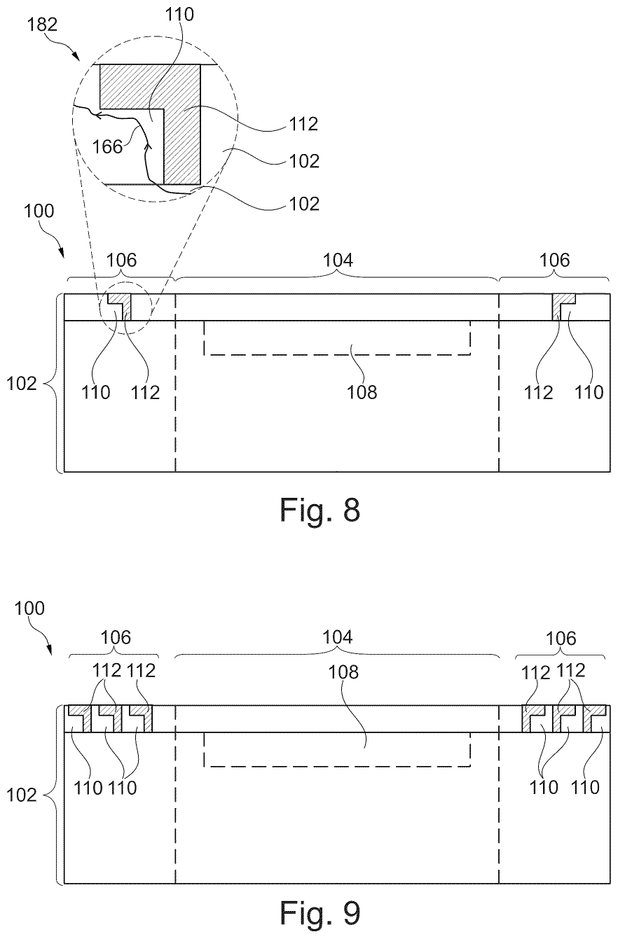

In an embodiment, the crack stop structure comprises one or more structures having an upside-down L-shape in a cross-sectional view (compare for example FIG. 8 or FIG. 9). With such a very simple configuration, a combined crack stop and guiding structure may be defined. Descriptively speaking, the metallic material of the inverted L-shaped structure may function for crack stopping, whereas the long leg and the short leg of the inverted L-shaped structure may guide a propagating crack with redirecting functionality, as described above.

In an embodiment, the electronic chip comprises at least one crack propagation inhibiting trench formed in the substrate and being configured for inhibiting horizontal propagation of a crack. Such a trench formed in a surface region of the substrate may interrupt horizontal trench propagation in an efficient way.

In an embodiment, the at least one crack propagation inhibiting trench is formed so that the crack guiding structure combined with the crack stop structure are arranged laterally between the at least one crack propagation inhibiting trench on the one hand and the active region on the other hand (see for example FIG. 3). Additionally or alternatively, the at least one crack propagation inhibiting trench is arranged laterally between the crack guiding structure combined with the crack stop structure on the one hand and a seal ring on the other hand. Additionally or alternatively, the at least one crack propagation inhibiting trench is arranged laterally between the crack guiding structure combined with the crack stop structure on the one hand and the active region on the other hand (for instance in the absence of a seal ring). Furthermore, other positions of a crack propagation inhibiting trench may be possible as well.

In an embodiment, the at least one crack propagation inhibiting trench is formed at least partially in a passivation layer (which may be a dielectric surface layer) of the substrate, in particular extending into a back end of the line (BEOL) dielectric of the substrate below the passivation layer. Hence, a simple trench extending vertically into a BEOL region may be sufficient for rendering horizontal cracks harmless.

In an embodiment, the method comprises separating the electronic chips from the wafer by mechanical dicing, by laser dicing, etc. However, any other die separation method can be used as well.

In an embodiment, the package is configured as one of the group consisting of a leadframe connected power module, a Transistor Outline (TO) package, a Quad Flat No Leads Package (QFN) package, a Small Outline (SO) package, a Small Outline Transistor (SOT) package, a Thin Small Outline Package (TSOP) package, etc. Also packages for sensors and/or mechatronic devices are possible embodiments. Moreover, exemplary embodiments may also relate to packages functioning as nano-batteries or nano-fuel cells or other devices with chemical, mechanical, optical and/or magnetic actuators. Therefore, the package according to an exemplary embodiment is fully compatible with standard packaging concepts (in particular fully compatible with standard TO packaging concepts) and appears externally as a conventional package, which is highly user convenient.

In an embodiment, the package is configured as power module, for instance molded power module such as a semiconductor power package. For instance, an exemplary embodiment of the package may be an intelligent power module (IPM). Another exemplary embodiment of the package is a dual inline package (DIP).

In an embodiment, the semiconductor component is configured as a power semiconductor chip. Thus, the semiconductor component (such as a semiconductor chip) may be used for power applications for instance in the automotive field and may for instance have at least one integrated insulated-gate bipolar transistor (IGBT) and/or at least one transistor of another type (such as a MOSFET, a JFET, etc.) and/or at least one integrated diode. Such integrated circuit elements may be made for instance in silicon technology or based on wide-bandgap semiconductors (such as silicon carbide). A semiconductor power chip may comprise one or more field effect transistors, diodes, inverter circuits, half-bridges, full-bridges, drivers, logic circuits, further devices, etc.

In an embodiment, the package comprises a plurality of electronic chips encapsulated by the encapsulant. Thus, the package may comprise one or more semiconductor components (for instance at least one passive component, such as a capacitor, and at least one active component).

As substrate or wafer forming the basis of the electronic chips, a semiconductor substrate, in particular a silicon substrate, may be used. Alternatively, a silicon oxide or another insulator substrate may be provided. It is also possible to implement a germanium substrate or a III-V-semiconductor material. For instance, exemplary embodiments may be implemented in GaN or SiC technology.

The above and other objects, features and advantages will become apparent from the following description and the appended claims, taken in conjunction with the accompanying drawings, in which like parts or elements are denoted by like reference numbers.

The illustration in the drawing is schematically and not to scale.

Before exemplary embodiments will be described in more detail referring to the figures, some general considerations will be summarized based on which exemplary embodiments have been developed.

Singulation methods used in semiconductor industry (in particular mechanical dicing, laser dicing and variants) may result in a significant reduction of an effective chip fracture strength.

In order to tackle this issue, crack stop structures have been conventionally implemented between chip side wall (where a crack in many cases starts) and the electrically active portion of the chip. These structures aim to force the propagating crack to lose energy before reaching the electrically active area. In some cases, this leads to a crack stopping inside such a structure without affecting the electrical functionality of the semiconductor device.

A weakness of such a conventional approach for the design of a crack stop is its incapability to prevent cracks from propagating into undesired regions of the electronic chip. To put it shortly, it is conventionally very difficult to keep cracks reliably outside of the active area. Furthermore, the described structure attempting to stop a propagating crack requires consumption of a high area, which may lead to a significant yield loss.

According to an exemplary embodiment, an electronic chip and a corresponding package are provided which are equipped with a robust crack guiding and stop construction in a chip edge portion. A substrate of the electronic chip may have a central portion and a partially or entirely surrounding edge portion. While an active region (in particular having one or more integrated circuit elements) may be arranged in said central portion, a crack guiding structure—configured for spatially guiding a crack which may be created during a dicing process—combined with a crack stop structure—which may be configured for decelerating or even stopping a generated crack—may be arranged in the edge portion. By taking this measure, initial defects and sub-micron cracks on chip side walls after singulation can be reliably avoided. To put it shortly, the crack guiding structure may guide a dicing-induced crack away from the critical active region towards a less critical region of the electronic chip or a wafer. The crack stop structure, being especially combined with the crack guiding structure, may block the crack and may thereby prevent propagation of the crack towards critical chip regions. At the same time, the crack stop structure may contribute to a deceleration or even stopping of a propagating crack by absorbing at least part of the energy of the crack. By the described combined crack guiding and stop structure, chip damaging effects of die separation-induced cracks may be mitigated or even eliminated. Thus, the yield of chip production may be significantly improved. At the same time, the space consumption of the combined crack guiding and stop structure may be very low, thereby rendering the manufacturing process highly efficient and ensuring a reasonable manufacturing effort. Hence, exemplary embodiments may reduce negative effects of intrinsic defects induced by singulation methods onto an electronics chip's active area. Exemplary embodiments may significantly improve the performance of crack stop structures at a die edge of silicon chips by implementing an integral crack guiding structure. Advantageously, this may improve the robustness of crack stop structures by actively directing cracks away from an active region of the electronic chip. Moreover, the combined formation of a crack guiding and crack stop structure may reduce the necessary area significantly. Beyond this, exemplary embodiments may enhance chip fracture strength.

In particular cracks being introduced, for example during chip separation, horizontally or having a significant horizontal component may be harmful for the integrity of an electronic chip, since such a crack may propagate towards an active region where an electronic chip may be most sensitive concerning damage. The combined crack guiding and stop structure of an exemplary embodiment may be located and configured so as to force a created crack at an early stage to propagate upwardly and therefore away from the active region. Since in particular horizontally propagating cracks may be critical for chip quality, a spatial redirection of such a crack from a substantially horizontal trajectory towards a substantially vertical trajectory may be of utmost advantage. Descriptively speaking, such a crack guiding path may be spatially embedded or integrated, for instance as a guide channel, inside of and delimited by a crack stop structure.

Exemplary embodiments have advantages: Firstly, the space consumption of the combined crack guiding and stop structure is very limited, which reduces the manufacturing effort. Advantageously, the combined crack guiding and stop structure may be manufactured in a spatially narrow way which leads to reduced effort and improved performance. In particular for high-frequency applications, resulting shorter bond wires may lead to enhanced performance. Furthermore, the combined crack guiding and stop structure may increase efficiency, since a dicing (for instance sawing) process may be accelerated or simplified, since even in the event of an increased amount of generated cracks a large percentage thereof may be guided away from the active region and may be finally stopped. By efficiently protecting an active region of an electronic chip by the combined crack guiding and stop structure, the reliability of the manufactured electronic chip and a corresponding package may be significantly improved. In particular for applications (such as automotive applications) with demanding requirements concerning quality and failure robustness, exemplary embodiments may be advantageously implemented. To put it shortly, an exemplary embodiment may involve smart crack guiding in an upward direction, wherein strain characteristics in a crystal lattice may be intelligently used for guiding cracks.

FIG. 1 illustrates a cross-sectional view of an electronic chip 100 according to an exemplary embodiment.

The illustrated electronic chip 100 comprises a substrate 102. Substrate 102 comprises a central portion 104 and an edge portion 106 extending around the central portion 104. An active region 108 is arranged in the central portion 104. Furthermore, a crack guiding structure 110 combined with a crack stop structure 112 are provided and are both arranged in the edge portion 106.

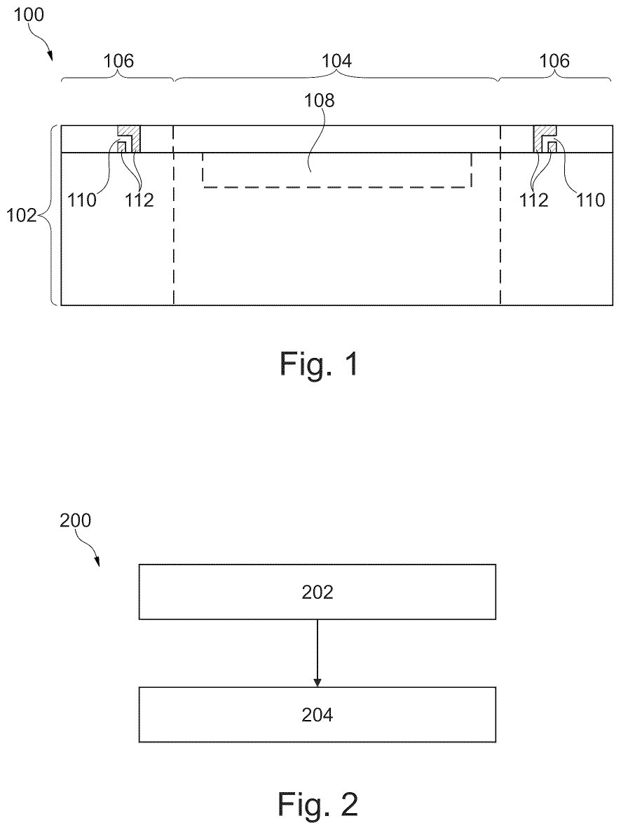

FIG. 2 illustrates a flowchart 200 of a manufacturing method according to an exemplary embodiment. The reference signs used for the following description of said manufacturing method relate to the embodiment of FIG. 1, unless otherwise noted.

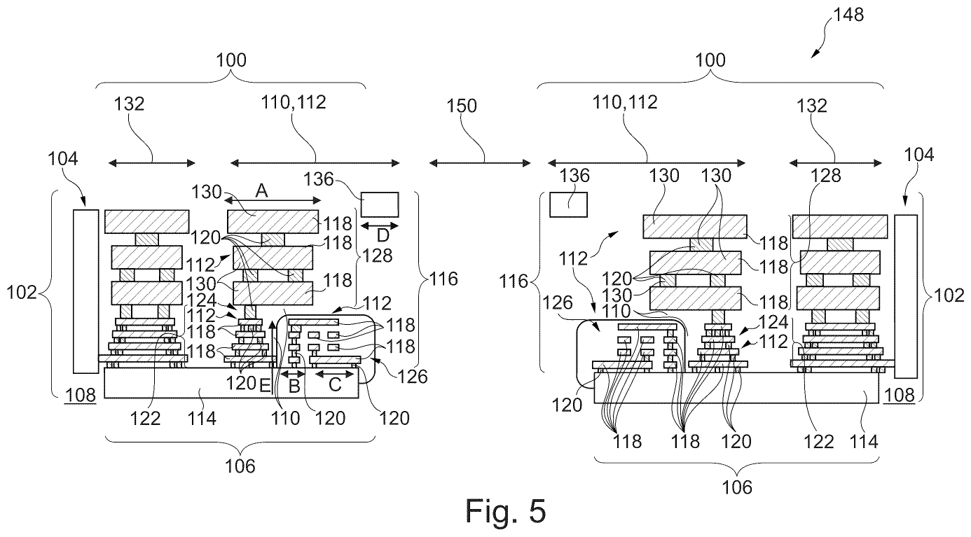

Referring to a block 202, the method comprises providing a wafer (see reference sign 148 in FIG. 5) comprising a plurality of integrally connected electronic chips 100. For example, each of said electronic chips 100 may be embodied as shown in FIG. 1.

Referring to a block 204, the method furthermore comprises separating the electronic chips 100 from the wafer 148 along separation lines (see reference sign 150 in FIG. 5). Said separation lines 150 may extend between adjacent edge portions 106 of the electronic chips 100. Consequently, at least part of cracks created during the separating may be guided along the crack guiding structures 110 and may be stopped by the crack stop structures 112.

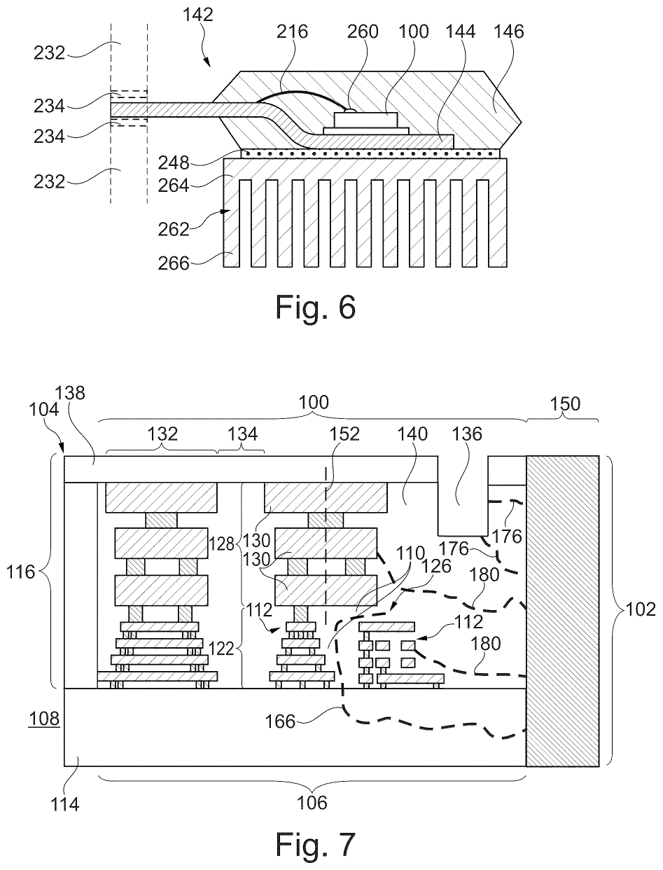

FIG. 3 illustrates a cross-sectional view of an electronic chip 100 according to an exemplary embodiment. The illustrated electronic chip 100 may be a bare die. However, it is also possible that the electronic chip 100 is encapsulated by an encapsulant (see reference sign 146 in FIG. 6), such as a mold compound.

The illustrated electronic chip 100 may for instance be a semiconductor chip. Electronic chip 100 comprises a substrate 102 having a bottom-sided semiconductor body 114, for instance made of silicon, and a top-sided back end of the line (BEOL) structure 116 on top of the semiconductor body 114. A passivation layer 138 may be formed on top of a BEOL dielectric 140. Within a horizontal plane, the electronic chip 100 comprises a central portion 104 (shown only partially) and an edge portion 106 (shown only partially as well) which circumferentially surrounds the central portion 104.

Although not shown in detail in FIG. 3, an active region (see reference sign 108 in FIG. 1) is arranged in the central portion 104. The active region 108 may comprise at least one monolithically integrated circuit element, such as a transistor, a diode, a capacitance, an inductance, or a more complex integrated circuitry such as an inverter. For example, the active region 108 may be formed in a top portion of the semiconductor body 114 and may be interconnected in the back end of the line structure 116 (not shown). The active region 108 may provide the actual functionality of the electronic chip 100.

The edge portion 106 of the electronic chip 100 forms an interface between said electronic chip 100 and an adjacent electronic chip when being singulated from a wafer compound during a dicing process. When such a wafer with commonly processed electronic chips 100 is separated into individual electronic chips 100 by dicing, said separation may occur for example by mechanically sawing or laser cutting through separation lines 150 (which may be denoted as scribe lines). A skilled person will appreciate that any other chip separation method may be executed as well. When the wafer compound is separated into individual electronic chips 100, cracks may be generated in the substrate 102, in particular in an interface region between semiconductor body 114 and back end of the line dielectric 140 of back end of the line structure 116. For example, a vertical thickness of the back end of the line dielectric 140 may be 10 μm. In said interface region, a transition from semiconductor material of semiconductor body 114 to dielectric and metallic material of back end of the line structure 116 occurs. This may cause stress which may be the origin of crack formation. When such cracks propagate through the substrate 102, they may even reach the central portion 104 and, in a worst-case, the active region 108 which may lead to a damage of the electronic chip 100 as a whole. As will be described below in further detail referring to FIG. 7, cracks may propagate along different paths. However, cracks with a significant horizontal motion component may be particularly critical, since they may involve a considerable risk of propagating up to the active region 108.

In order to tackle the challenging cracks for ensuring integrity of the electronic chips 100, a crack guiding structure 110 combined with a crack stop structure 112 may be both being arranged in the edge portion 106. More specifically, the crack guiding structure 110 combined with the crack stop structure 112 may form part of the back end of the line structure 116.

As shown, the crack guiding structure 110 may be integrated in the crack stop structure 112 which leads to a very small space consumption of the crack defeating structure.

Now referring in detail to the crack guiding structure 110, the latter defines a spatially confined crack propagation path inside of the crack stop structure 112. More specifically, the crack guiding structure 110 is here formed as a dielectric channel within metallic constituents of the metallic crack stop structure 112 and may have an inverted L-shape in the embodiment of FIG. 3. As a result of its shape and its embedding inside of the metallic constituents of the metallic crack structure 112, the crack guiding structure 110 is configured for redirecting a propagation direction of a crack when passing the crack guiding structure 110 combined with the crack stop structure 112. When a crack occurs at a bottom side of the illustrated crack guiding structure 110 combined with the crack stop structure 112, the crack may propagate through the electronic chip 100 along a path of least mechanical resistance. An exemplary enforced crack propagation path is indicated by reference sign 166 in FIG. 3. In the shown configuration, a substantially horizontally propagating crack will enter into the dielectric channel-type crack guiding structure 110, as a region of least mechanical resistance. In this context, the substantially horizontally propagating crack moving towards the active region 108 will be redirected to move vertically upwardly through the vertical portion of the channel-type crack guiding structure 110 before being redirected again to move again horizontally along a horizontal portion (directly connected to said vertical portion) of the channel-type crack guiding structure 110 but now along a direction away from the active region 108. In other words, the illustrated crack guiding structure 110 is configured for redirecting a crack propagating initially towards the active region 108 into an upwardly propagating crack, and for further redirecting the upwardly propagating crack into a crack propagating laterally away from the active region 108, as shown with reference sign 166. This controlled double redirection will guide the crack away from the critical active region 108 into a less harmful region of the electronic chip 100 where the crack will not damage the functionally active portion of the electronic chip 100. Thus, the crack guiding structure 110 defines a dielectric path—with lower mechanical resistance than its environment—delimited by metallic structures of the crack stop structure 112. More specifically, said dielectric path comprises a bottom-sided upward path section merging into a top-sided lateral path section.

Now referring in further detail to the crack stop structure 112, the latter is embodied as a metallic structure configured for stopping a propagating crack which may involve absorption of kinetic energy of the crack. As shown, the crack stop structure 112 comprises horizontal metallic structures 118 and vertical metallic structures 120. The horizontal metallic structures 118 may form part of patterned metal layers, whereas the vertical metallic structures 120 may interconnect vertically spaced horizontal metallic structures 118 and may be embodied as metallic vias. The horizontal metallic structures 118 and the vertical metallic structures 120 of the crack stop structure 112 may also delimit the dielectric crack guiding channel of crack guiding structure 110. Furthermore, the horizontal metallic structures 118 and the vertical metallic structures 120 may be embedded in the back end of the line dielectric 140 of the back end of the line structure 116.

Functionally, a bottom-sided portion 122 and a top-sided portion 128 of the crack stop structure 112 may be distinguished:

Said bottom-sided portion 122 of the crack stop structure 112 comprises, on the left-hand side, a crack barrier section 124 facing the active region 108 and comprises, on the right-hand side, a sacrificial section 126 facing away from the active region 108.

Descriptively speaking, the crack barrier section 124 functions as a rigid metallic wall which prevents propagating cracks from approaching the active region 108 in the central portion 104 of the substrate 102. Thus, the crack barrier section 124 is configured as a barrier inhibiting propagation of a crack through the crack barrier section 124 towards the active region 108. For this purpose, the crack barrier section 124 comprises a continuously interconnected vertical arrangement of horizontal metallic structures 118 and vertical metallic structures 120. More precisely, each pair of adjacent horizontal metallic structures 118 in the crack barrier section 124 may be interconnected by at least one respective vertical metallic structure 120 in between. The crack barrier section 124 is constructed for withstanding cracks without being destroyed itself when interacting with the crack.

In contrast to this, the sacrificial section 126—being located remote or further away from the active region 108 in comparison with the crack barrier section 124—can be constructed so as to be intentionally destroyed, i.e. sacrificed, when interacting with a crack. This is however not harmful for the active region 108, since the sacrificial section 126 is located remote from the active region 108 and separated from the active region 108 by the robust crack barrier section 124. Furthermore, the self-destroying function of the sacrificial section 126 may absorb a significant amount of energy of a crack, and may thereby efficiently decelerate or even stop the crack. Unlike the crack barrier section 124, only a part of the pairs of adjacent horizontal metallic structures 118 in the sacrificial section 126 are interconnected by a respective vertical metallic structure 120 in between, whereas another part of the pairs of adjacent horizontal metallic structures 118 of the sacrificial section 126 remain unconnected, i.e. are not linked by a vertical metallic structure 120 in between. More specifically, the sacrificial section 126 comprises horizontal metallic structures 118 and vertical metallic structures 120, wherein a part of the horizontal metallic structures 118 is interconnected with the vertical metallic structures 120, and wherein another part of the horizontal metallic structures 118 is separated from the vertical metallic structures 120. Hence, a via density (such as a number of vias per volume) may be smaller in the sacrificial section 126 in comparison with the crack barrier section 124. In other words, the sacrificial section 126 may be characterized by a locally reduced via density. Hence, a number of vertical metallic structures 120 per volume may be larger in the crack barrier section 124 than in the sacrificial section 126, which further promotes the pronounced mechanical strength of the crack barrier section 124 as compared with the limited mechanical strength of the sacrificial section 126. Thus, the sacrificial section 126 is configured for being at least partially destroyed by a crack propagating to the crack stop structure 112. This selectively weakens the sacrificial section 126 for promoting its intended crack energy absorbing function.

Still referring to FIG. 3, it is illustrated that the crack guiding structure 110 may extend between the crack barrier section 124 and the sacrificial section 126. This may also ensure an efficient interaction between a guided crack and the crack stop structure 112.

Directly structurally coupled with the bottom-sided portion 122 of the crack stop structure 112, a top-sided portion 128 of the crack stop structure 112 is foreseen, as shown in FIG. 3 as well. The top-sided portion 128 of the crack stop structure 112 comprises an asymmetric metallic bulk structure 130 having a higher amount of metal per volume on a side facing the active region 108 than on an opposing side facing away from the active region 108. On the left-hand side of crack stop structure 112, said top-sided portion 128 comprises the metallic bulk structure 130 extending vertically from and being connected with the crack barrier section 124. However, said metallic bulk structure 130 is separated by a vertical spacing, d, from the sacrificial section 126 and extends as a cantilever laterally over part of the sacrificial section 126. The vertical spacing, d, forms the vertical section of the crack guiding channel connecting the semiconductor body 114 with a portion of the back end of the line dielectric 140 facing away from the active region 108 of the electronic chip 100. A diameter of the crack guiding channel may be in a range from 0.5 μm to 5 μm, for instance 0.9 μm.

Again referring to FIG. 3, the crack stop structure 112 comprises a plurality of vertically stacked and mutually spaced horizontal metal structures 118 having different thicknesses l1<l2<l3 which increase from bottom to top of the crack stop structure 112. In the region of the metallic bulk structure 130, a vertical thickness of the horizontal metal structures 118 inside the back end of the line dielectric 140 is maximum. In the shown embodiment, the four lower horizontal metal structures 118 have a thickness 11 being smaller than a thickness 12 of the fifth horizontal metallic structure 118 being, in turn, smaller than a thickness 13 of an uppermost horizontal metallic structure 118. Due to this thickness distribution, the metallic bulk structure 130 may have a higher amount of metal per volume than each of the crack barrier section 124 and the sacrificial section 126 of the bottom-sided portion 122 of the crack stop structure 112. Thus, bulk metal is concentrated in the upper portion of the crack stop structure 112, and in particular in the metallic bulk structure 130. Consequently, the metallic bulk structure 130 may provide a huge contribution to crack stopping.

As shown, the metallic bulk structure 130 of the top-sided portion 128 of the crack stop structure 112 is asymmetrically connected at its bottom side only with the crack barrier section 124, but not with the sacrificial section 126. The asymmetry of the crack stop structure 112 corresponds to the fact that the crack stop structure 112 has an asymmetric metal distribution with respect to a vertical central axis 160 through the crack stop structure 112. This has advantages: On the one hand, this promotes the intended weak mechanical stability of the sacrificial section 126 (which is not reinforced by the spatially separated metallic bulk structure 130) which may contribute to an efficient transfer of crack energy to the sacrificial section 126 being thereby destroyed. On the other hand, the asymmetric foot assembly of the metallic bulk structure 130 may lead to a tilting and even to a collapse of the metallic bulk structure 130 when cracks exert stress to the metallic bulk structure 130 during dicing.

In addition to the aforementioned metallic structures 118, 120 constituting the crack stop structure 112, a seal ring 132 is arranged laterally between the active region 108 on the one hand and the crack guiding structure 110 combined with the crack stop structure 112 on the other hand. Functionally, the seal ring 132 is configured for protecting the active region 108 against moisture and charged particles. Apart from this, seal ring 132 may function as last line of defence for cracks approaching active region 108. Furthermore, seal ring 132 may be optionally grounded for providing an electric protection function. Advantageously, the seal ring 132 may be formed in a common manufacturing process carried out for forming the crack stop structure 112. For instance, this may be achieved by forming horizontal metallic structures 118 of the seal ring 132 and of the crack stop structure 112 at the same vertical level by patterning a respective common metal layer. Correspondingly, this may be achieved by forming vertical metallic structures 120 of the seal ring 132 and of the crack stop structure 112 at the same vertical level by depositing metal for simultaneously forming vias. Despite of their same material composition, the crack stop structure 112 and the seal ring 132 fulfil completely different functions, as a result of their fundamentally different positions and structural configurations. For example, seal ring 132 may have a completely symmetric metallic configuration, whereas the crack stop structure 112 preferably has an asymmetric metallic configuration (in particular for promoting deformation of a dedicated portion thereof in the presence of crack stress).

Moreover, electronic chip 100 comprises at its upper main surface an inspection zone 134 for optical inspection of integrity of the electronic chip 100. This optical inspection zone 134 is arranged laterally between the seal ring 132 on the one hand and the crack guiding structure 110 combined with the crack stop structure 112 on the other hand. When inspecting the inspection zone 134 by an optical inspection camera (not shown) or by a human operator (not shown as well), the presence or absence of a crack-caused destruction in the inspection zone 134 can be used as a reliable indicator whether or not the electronic chip 100 can be classified as intact or defective.

Furthermore, the electronic chip 100 according to FIG. 3 comprises a crack propagation inhibiting trench 136 formed in a top portion of the substrate 102 and being configured for inhibiting horizontal propagation of a crack. Descriptively speaking, when a crack propagates substantially horizontally along a surface of the substrate 102 and reaches the crack propagation inhibiting trench 136, its propagation is fundamentally disturbed due to the structural discontinuity introduced by the presence of the trench 136. Hence, further propagation of the crack may be efficiently inhibited by the trench 136. In particular edges 174 at a bottom of the trench 136 may be regions of maximum local stress, which may have a crack attracting effect. Descriptively speaking, the trench 136 may filter out surface-near cracks. A depth of the trench 136 may be for example in a range from 0.5 μm to 5 μm, for instance 1.5 μm. A width of the trench 136 may be for example in a range from 2 μm to 4 μm, for example 3 μm.

In the shown embodiment, the crack propagation inhibiting trench 136 is formed so that the crack guiding structure 110 combined with the crack stop structure 112 are arranged laterally between the crack propagation inhibiting trench 136 on the one hand and the active region 108 on the other hand. This has turned out as a highly appropriate position for crack propagation inhibiting trench 136. However, it may also be possible, additionally or alternatively, to form a crack propagation inhibiting trench 136 laterally between the crack guiding structure 110 combined with the crack stop structure 112 on the one hand and the seal ring 132 on the other hand. In the absence of optional seal ring 132, such a crack propagation inhibiting trench 136 may also be arranged laterally between the crack guiding structure 110 combined with the crack stop structure 112 on the one hand and the active region 108 on the other hand.

According to FIG. 3, the crack propagation inhibiting trench 136 may be formed partially in passivation layer 138 and partially in the back end of the line dielectric 140 below the passivation layer 138. To put it shortly, implementation of one or more trenches 136 in passivation layer 138 and back end of the line dielectric 140 may function as delamination stopper.

Summarizing, the combined crack guiding structure 110 and crack stop structure 112 may be constructed with a combination of a crack arresting structure—in the region of sacrificial section 126—and a crack stop—in the region of metallic bulk structure 130—as one structure. By the decoupled arrangement between sacrificial section 126 on the one hand and crack barrier section 124 and metallic bulk structure 130 on the other hand, it may be possible to form in between the crack guiding structure 110 for spatially guiding cracks in a controlled way. Descriptively speaking, the crack guiding structure 110 can be formed as a dielectric non-metallic recess inside of the crack stop structure 112. Due to the partial omission of vias in the sacrificial section 126, absorption of crack energy in the sacrificial section 126 may be additionally promoted.

Furthermore, formation of zone 134 for automated optical inspection between seal ring 132 and the crack arresting structure may simplify a quality inspection process.

Advantageously, the configuration of FIG. 3 leads to an area saving when forming the combined crack guiding structure 110 and crack stop structure 112. Furthermore, a high robustness may be achieved. Moreover, placement of an automated optical inspection zone 134 between crack stop structure 112 and seal ring 132 may help to improve yield loss after separation.

Reference sign 168 in FIG. 3 indicates an optional chip connection element, for instance made of polycrystalline silicon material.

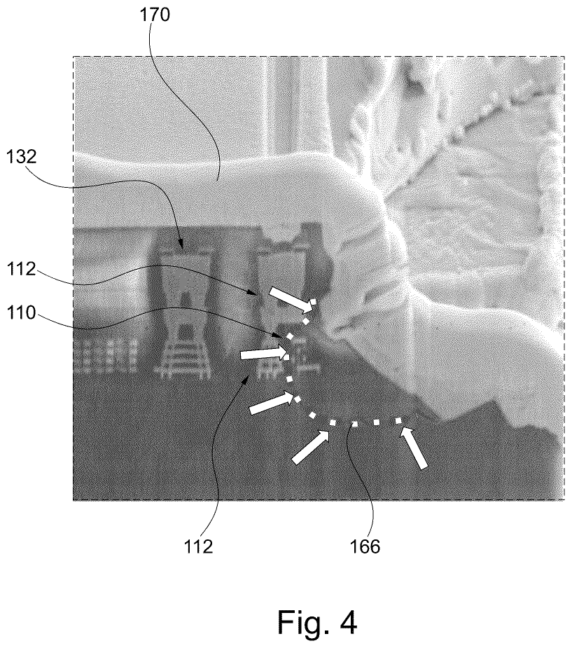

FIG. 4 illustrates an image of an electronic chip 100 according to another exemplary embodiment.

The construction of FIG. 4 corresponds substantially to the construction explained above referring to FIG. 3. Reference sign 170 in FIG. 4 shows an artifact of a preparation for capturing the shown image. Arrows in FIG. 4 in combination with reference sign 166 show a typical crack propagation path.

FIG. 5 illustrates a cross-sectional view of electronic chips 100 a common wafer 148 according to an exemplary embodiment.

According to FIG. 5, the electronic chips 100 may still form integral part of common wafer 148, such as a silicon wafer. For separating individual electronic chip 100, the wafer 148 may be diced into individual electronic chips 100 in a dicing area by dicing along separation lines 150. Cracks created during dicing may be guided and stopped by a respective crack guiding structure 110 combined with the assigned crack stop structure 112, for protecting each active region 108 of each electronic chip 100. Each respective crack guiding structure 110 combined with the assigned crack stop structure 112 may circumferentially surround the entire active region 108 of the respective electronic chip 100. Thus, each respective crack guiding structure 110 combined with the assigned crack stop structure 112 may form an annular structure.

Several structural features A, B, C, D, E for crack management are indicated in FIG. 5:

As shown, the die area between two neighboured electronic chips 100 contains a seal-ring 132, a crack stop structure 112 integrally formed with a crack guiding structure 110, and the dicing area shown with reference sign 150. The crack stop structure 112 comprises parts B, C, and part D also contributes to crack stopping. Part D shows trench 136 in the passivation layer 138. Part C is composed of spread-out metal structures which can extend to the passivation trench 136 according to reference sign D (until trench 136 or including trench 136).

The metal layers (partially without via-contacts) of sacrificial section 126 can be destroyed by cracking and are able to absorb crack energy.

Metal layers in part B are connected in-between each other. The upper metal layer of part B acts as cover over part C. The structures B and C keep a crack away from the integrated circuit region of electronic chip 100.

The cascaded structure of A, B and C supports the guidance of a crack in direction to the chip surface (i.e. away from active region 108). Due to the decoupled structure between A, B and C, metal free paths E are created. These paths allow determined crack propagation away from the active region 108 into uncritical areas and constitute crack guiding structure 110.

FIG. 6 illustrates a cross-sectional view of a molded semiconductor package 142 according to an exemplary embodiment.

The shown package 142 comprising a carrier 144, an electronic chip 100 according to FIG. 1, FIG. 3 or FIG. 5 mounted on the carrier 144, and an encapsulant 146 encapsulating the electronic chip 100 and part of the carrier 144.

The semiconductor package 142 is mounted on a mounting structure 232, here embodied as printed circuit board.

The mounting structure 232 comprises an electric contact 234 embodied as a plating in a through hole of the mounting structure 232. When the semiconductor package 142 is mounted on the mounting structure 232, the electronic chip 100 of the semiconductor package 142 is electrically connected to the electric contact 234 via electrically conductive carrier 144, here embodied as a leadframe made of copper.

As can be taken from FIG. 6, a pad 260 on an upper main surface of the electronic chip 100 is electrically coupled to the carrier 144 via a bond wire as electrically conductive connection element 216. Alternatively, a clip may be used as electrically conductive connection element 216 (not shown).

During operation of the power semiconductor package 142, the power semiconductor chip in form of the electronic chip 100 generates a considerable amount of heat. At the same time, it shall be ensured that any undesired current flow between a bottom surface of the semiconductor package 142 and an environment is reliably avoided.

For ensuring electrical insulation of the electronic chip 100 and removing heat from an interior of the electronic chip 100 towards an environment, an electrically insulating and thermally conductive interface structure 248 may be provided which covers an exposed surface portion of the carrier 144 and a connected surface portion of the encapsulant 146 at the bottom of the semiconductor package 142. The electrically insulating property of the interface structure 248 prevents undesired current flow even in the presence of high voltages between an interior and an exterior of the semiconductor package 142. The thermally conductive property of the interface structure 248 promotes a removal of heat from the electronic chip 100, via the electrically conductive carrier 144 (of thermally properly conductive copper), through the interface structure 248 and towards a heat dissipation body 262. The heat dissipation body 262, which may be made of a highly thermally conductive material such as copper or aluminum, has a base body 264 directly connected to the interface structure 248 and has a plurality of cooling fins 266 extending from the base body 264 and in parallel to one another so as to remove the heat towards the environment.

The package configuration according to FIG. 6 is only exemplary, since the chip manufacturing process according to exemplary embodiments may be compatible with many package types.

FIG. 7 illustrates a cross-sectional view of an electronic chip 100 according to yet another exemplary embodiment in which different kinds of cracks variants are illustrated.

One highly relevant crack propagation path is shown with reference sign 166. As explained above, such kind of crack may propagate horizontally along a bottom side of the combined crack guiding structure 110 and crack stop structure 112 and will be attracted by the channel-type crack guiding structure 110 being spatially delimited between different sections of the crack stop structure 110. Descriptively speaking, the horizontally propagating crack will follow the path of least mechanical resistance and will therefore enter the channel-type crack guiding structure 110 so as to be guided away from active region 108 and being stopped.

A further relevant crack propagation path is shown with reference sign 176. Such a surface-near crack may be filtered out by trench 136 and may therefore be prevented from approaching or even reaching active region 108.

Apart from this, FIG. 7 shows further cracks with reference sign 180 which can be stopped or reflected by the various constituents of crack stop structure 112.

It is understood that the cracks illustrated in FIG. 7 are shown for illustrative purposes only, and that additional and/or alternative types of cracks may occur in practice.

FIG. 8 illustrates a cross-sectional view of an electronic chip 100 according to yet another exemplary embodiment.

A difference between the embodiment of FIG. 8 and the embodiment of FIG. 1 is that, according to FIG. 8, the crack stop structure 112 comprises a metallic structure having an upside-down L-shape in the shown cross-sectional view. The illustrated crack stop structure 100 has a ring shape with outwardly oriented metallic extensions on the top side. Consequently, cracks may be guided along an outside of the crack stop structure 112 and along the crack guiding structure 110 for redirecting the cracks towards uncritical regions of the electronic chip 104. This is illustrated in a detail 182.

FIG. 9 illustrates a cross-sectional view of an electronic chip 100 according to still another exemplary embodiment.

A difference between the embodiment of FIG. 9 and the embodiment of FIG. 8 is that, according to FIG. 9, the crack stop structure 112 comprises a plurality of concentric annular metallic structures having an upside-down L-shape in the shown cross-sectional view. Adjacent to the crack stop structure 112 and in between adjacent portions of the crack stop structure 112, respective portions of the crack guiding structure 110 may be delimited.

It should be noted that the term “comprising” does not exclude other elements or features and the “a” or “an” does not exclude a plurality. Also elements described in association with different embodiments may be combined. It should also be noted that reference signs shall not be construed as limiting the scope of the claims. Moreover, the scope of the present application is not intended to be limited to the particular embodiments of the process, machine, manufacture, composition of matter, means, methods and steps described in the specification. Accordingly, the appended claims are intended to include within their scope such processes, machines, manufacture, compositions of matter, means, methods, or steps.

What is claimed is:

1. An electronic chip, comprising:
a substrate comprising a central portion and an edge portion around at least part of the central portion;
an active region arranged in the central portion; and
a crack guiding structure combined with a crack stop structure, both being arranged in the edge portion.

2. The electronic chip according to claim 1, wherein the crack guiding structure defines a spatially confined crack propagation path at least partially inside of the crack stop structure.

3. The electronic chip according to claim 1, wherein the crack guiding structure is configured for redirecting a propagation direction of a crack when passing the crack guiding structure combined with the crack stop structure.

4. The electronic chip according to claim 1, wherein the crack guiding structure is configured for redirecting a crack propagating towards the active region into an upwardly propagating crack, wherein in particular the crack guiding structure is configured for further redirecting the upwardly propagating crack into a crack propagating laterally away from the active region.

5. The electronic chip according to claim 1, wherein the crack stop structure is configured for stopping a crack, as a barrier for a crack and/or for absorbing energy of a crack.

6. The electronic chip according to claim 1, wherein the substrate comprises a semiconductor body with a back end of the line structure thereon, and wherein the crack guiding structure combined with the crack stop structure form part of the back end of the line structure.

7. The electronic chip according to claim 1, wherein the crack guiding structure defines a dielectric path delimited by metallic structures of the crack stop structure, wherein in particular the dielectric path comprises a bottom-sided upward path section merging into a top-sided lateral path section.

8. The electronic chip according to claim 1, wherein the crack stop structure comprises horizontal metallic structures and vertical metallic structures.

9. The electronic chip according to claim 1, wherein a bottom-sided portion of the crack stop structure comprises a crack barrier section facing the active region and comprises a sacrificial section facing away from the active region, wherein at least part of the crack guiding structure extends between the crack barrier section and the sacrificial section.

10. The electronic chip according to claim 9, comprising at least one of the following features:
wherein the crack barrier section is configured as a barrier for inhibiting propagation of a crack through the crack barrier section towards the active region;
wherein the crack barrier section comprises a continuously interconnected vertical arrangement of horizontal metallic structures and vertical metallic structures;
wherein the sacrificial section is configured for being at least partially destroyed by a crack propagating to the crack stop structure;
wherein the sacrificial section comprises horizontal metallic structures and vertical metallic structures, wherein a part of the horizontal metallic structures is interconnected with the vertical metallic structures, and wherein another part of the horizontal metallic structures is separated from the vertical metallic structures.

11. The electronic chip according to claim 9, wherein a top-sided portion of the crack stop structure comprises a metallic bulk structure extending vertically from and being connected with the crack barrier section.

12. The electronic chip according to claim 11, wherein the metallic bulk structure is separated by a vertical spacing from the sacrificial section and extends laterally over at least part of the sacrificial section.

13. The electronic chip according to claim 1, wherein the crack stop structure comprises a plurality of vertically stacked and mutually spaced horizontal metal structures having a thickness which increases from bottom to top of the crack stop structure.

14. The electronic chip according to claim 1, comprising a seal ring arranged laterally between the active region on the one hand and the crack guiding structure combined with the crack stop structure on the other hand.

15. The electronic chip according to claim 1, comprising at least one of the following features:
the electronic chip is configured as bare die;
the crack stop structure is asymmetric with respect to a vertical central axis through the crack stop structure;
the crack stop structure comprises one or more structures having an upside-down L-shape in a cross-sectional view.

16. The electronic chip according to claim 1, comprising at least one crack propagation inhibiting trench formed in the substrate and being configured for inhibiting horizontal propagation of a crack.

17. The electronic chip according to claim 16, comprising at least one of the following features:
wherein the at least one crack propagation inhibiting trench is formed so that the crack guiding structure combined with the crack stop structure are arranged laterally between the at least one crack propagation inhibiting trench on the one hand and the active region on the other hand;
wherein the at least one crack propagation inhibiting trench is arranged laterally between the crack guiding structure combined with the crack stop structure on the one hand and a seal ring on the other hand;
wherein the at least one crack propagation inhibiting trench is arranged laterally between the crack guiding structure combined with the crack stop structure on the one hand and the active region on the other hand;
wherein the at least one crack propagation inhibiting trench is formed at least partially in a passivation layer of the substrate, in particular extending into a back end of the line dielectric of the substrate below the passivation layer.

18. A package, comprising:
a carrier;
an electronic chip according to claim 1 mounted on the carrier; and
an encapsulant encapsulating at least part of the electronic chip and the carrier.

19. A manufacturing method, wherein the method comprises:
providing a wafer comprising a plurality of integrally connected electronic chips according to claim 1; and
separating the electronic chips from the wafer along separation lines extending between adjacent edge portions of the electronic chips so that at least part of cracks created during the separating are guided along the crack guiding structures and/or are stopped by the crack stop structures.

20. The method according to claim 19, wherein the method comprises separating the electronic chips from the wafer by mechanical dicing, by laser dicing, or by another chip separation technique.
